(19) United States
(12) Patent Application Publication
(10) Pub. No.: US 2010/0271762 A1
(43) Pub. Date: Oct. 28, 2010

(54) SHIELDING DEVICE AND DISPLAY DEVICE HAVING THE SAME

(76) Inventors: Chin-Fu Chiang, Hsin-Chu (TW); Chih-Wen Li, Hsin-Chu (TW); Da-Wei Liu, Hsin-Chu (TW); Wei-Chen Yu, Hsin-Chu (TW)

Correspondence Address: NORTH AMERICA INTELLECTUAL PROPERTY CORPORATION, P.O. BOX 506, MERRIFIELD, VA, 22116, US

(21) Appl. No.: 12/607,038

(22) Filed: Oct. 27, 2009

(30) Foreign Application Priority Data
Apr. 24, 2009 (TW) 098113683

(51) Int. Cl. H05K 7/00

(52) U.S. Cl. 361/679.01

(57) ABSTRACT

A shielding device provides a housing, a lid and a connection hole, and the shielding device is fireproof, insulating, and easy for wire assembly. The housing is disposed on an electronic device and surrounds the electronic device. The housing has at least one opening corresponding to a connector of the electronic device. The perimeter of the lid is connected to the perimeter of the opening, so that the lid can cover the opening to shield the connector. The connection hole is disposed on at least one of the perimeter of the opening and the perimeter of the lid. When the lid covers the opening of the housing, at least one connecting wire of the electronic device can extend outwardly through the shielding device via the connection hole.

### BACKGROUND OF THE INVENTION

1. Field of the Invention

The present invention relates to a shielding device and a display associated therewith, and more particularly, to a shielding device that is nonflammable, insulating, and in favor of wire assembly.

2. Description of the Prior Art

In order to meet the requirements of safety standards, devices that tend to induce fire and electric shock, such as printed circuit boards (PCBs) of a display, have to be shielded by materials being nonflammable and insulating. FIG. 1 shows a convention structure of a liquid crystal TV. As shown in FIG. 1, a liquid crystal TV 10 contains a front shell 12 and a back shell 14. The front shell 12 and the back shell 14 respectively cover a liquid crystal display module 16, printed circuit boards 18, and other components. In addition, both the front shell 12 and the back shell 14 must be made of materials that are nonflammable and insulating to isolate the flammable and leakable printed circuit boards 18 from the outside. The fireproof and insulating abilities of the liquid crystal TV 10 will thus be improved to comply with the requirements of safety standards.

Although the design of the front shell 12 and the back shell 14 of the liquid crystal TV 10 may increase its safety level, non-flammable and insulating materials are still considered expensive. The front shell 12 and the back shell 14 have to cover the whole liquid crystal display module 16 and printed circuit boards 18, which will lead to a high material cost. Particularly, as the market demand and display technique increase, the size of the liquid crystal TV 10 has been increased as well so that the material quantity and fabrication cost of the front shell 12 and the back shell 14 will be raised accordingly.

Currently, there are liquid crystal TVs with shielding devices for enhancing their fireproofing and insulating effects. For example, the peripheral of the printed circuit boards are designed to be covered by a nonflammable and insulating shielding cover, which however does not cover the peripheral of the liquid crystal display module. What is more, the front shell and the back shell are not made of nonflammable and insulating materials to reduce the cost of liquid crystal TVs. Nevertheless, the shielding cover must contain an opening for the connecting wire to pass through the shielding cover and be connected to printed circuit boards. Further, the size of the connecting wire is generally much larger than the diameter of the connecter itself. For taking account of the convenience of connecting wire assembly, the gap between the connecting wire and the opening of the shielding cover will become large. As a result, it is difficult to meet required effects of being nonflammable and insulating; thus, it is difficult to meet the requirements of safety standards.

Another design to solve the safety problems is to apply an extra fastening element to the opening of the shielding cover after installing the shielding cover and the connecting wire completely to fill the gap between the connecting wire and the opening. However, the extra fastening element will increase not only the cost but also the complication of connecting wire assembly and display rework.

In view of abovementioned issues, it is desired to offer a shielding device that is nonflammable, insulating, and in favor of wire assembly so as to comply with the requirements of safety standards of a display as well as to reduce its cost.

### SUMMARY OF THE INVENTION

Therefore, it is one of the objectives of the present invention to provide a shielding device as well as a display associated to it that are nonflammable, insulating, and in favor of wire assembly in order to solve the abovementioned problems.

In accordance with an embodiment of the present invention, a shielding device, which is disposed on an electronic device and surrounds the electronic device, is provided. The shielding device includes a housing having at least one opening corresponding to a connector of the electronic device; a lid covering the opening to shield the connector, a perimeter of the lid connected to a perimeter of the opening; and a connection hole disposed on at least one of the perimeter of the opening and the perimeter of the lid.

The present invention further provides a display including a display module, a circuit board, a shielding device, a front frame, and a back shell. The display module has a display screen and a back surface opposing it, and the circuit board is disposed on the back surface of the display module. In addition, the shielding device, disposed on the circuit board and surrounding the circuit board, includes a housing, a lid, and a connection hole, wherein the housing has at least one opening corresponding to a connector of the circuit board. The lid covers the opening to shield the connector, and a perimeter of the lid is connected to a perimeter of the opening. The connection hole is disposed on at least one of the perimeter of the opening and the perimeter of the lid. Lastly, the front frame is disposed at a side of the display module opposing the circuit board and exposes the display screen of the display module while the back shell covers the back surface of the display module and the shielding device.

When the opening of the housing is covered by the lid, the connecting wire of the circuit board will extend outwardly via the connection hole. As a result, the shielding device provided by the present invention not only effectively reduces the exposure area of the electronic device but also enhances the convenience of wire assembly and rework of displays.

### BRIEF DESCRIPTION OF THE DRAWINGS

FIG. 1 is a structural schematic diagram according to a conventional liquid crystal television module.

FIGS. 2 to 7 are schematic diagrams showing a shielding device according to a first preferred embodiment of the present invention.

FIG. 8 is a schematic diagram showing a shielding device having a display according to a preferred embodiment of the present invention.

FIGS. 9 to 11 are schematic diagrams showing a shielding device according to a second to a fourth preferred embodiments of the present invention.

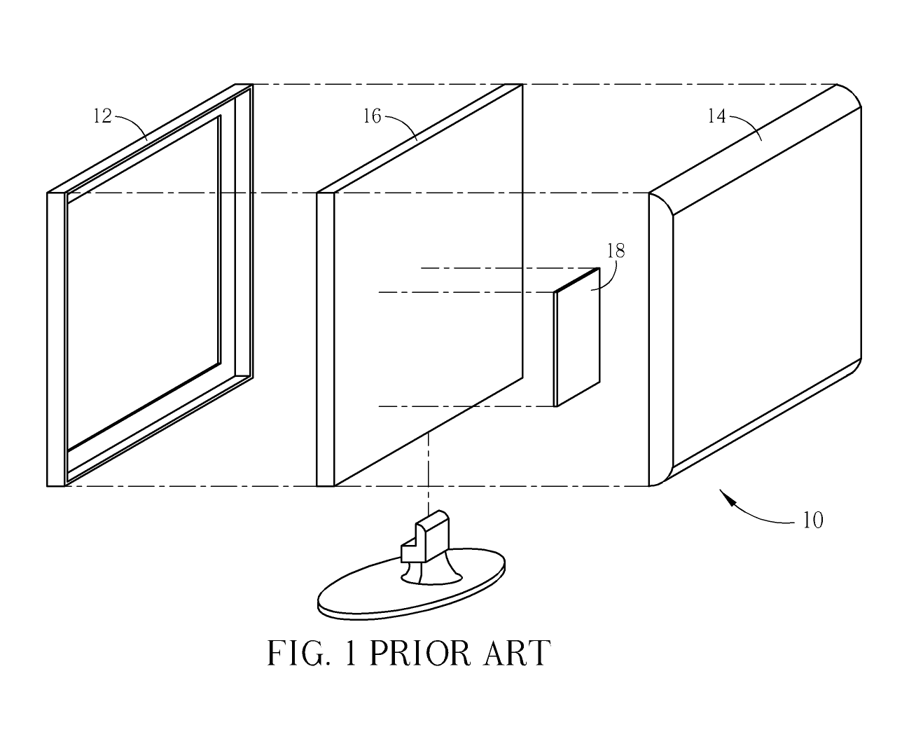

### DETAILED DESCRIPTION

These and other objectives of the present invention will no doubt become obvious to those of ordinary skill in the art after reading the following detailed description of the preferred embodiments that are illustrated in the various figures and drawings.

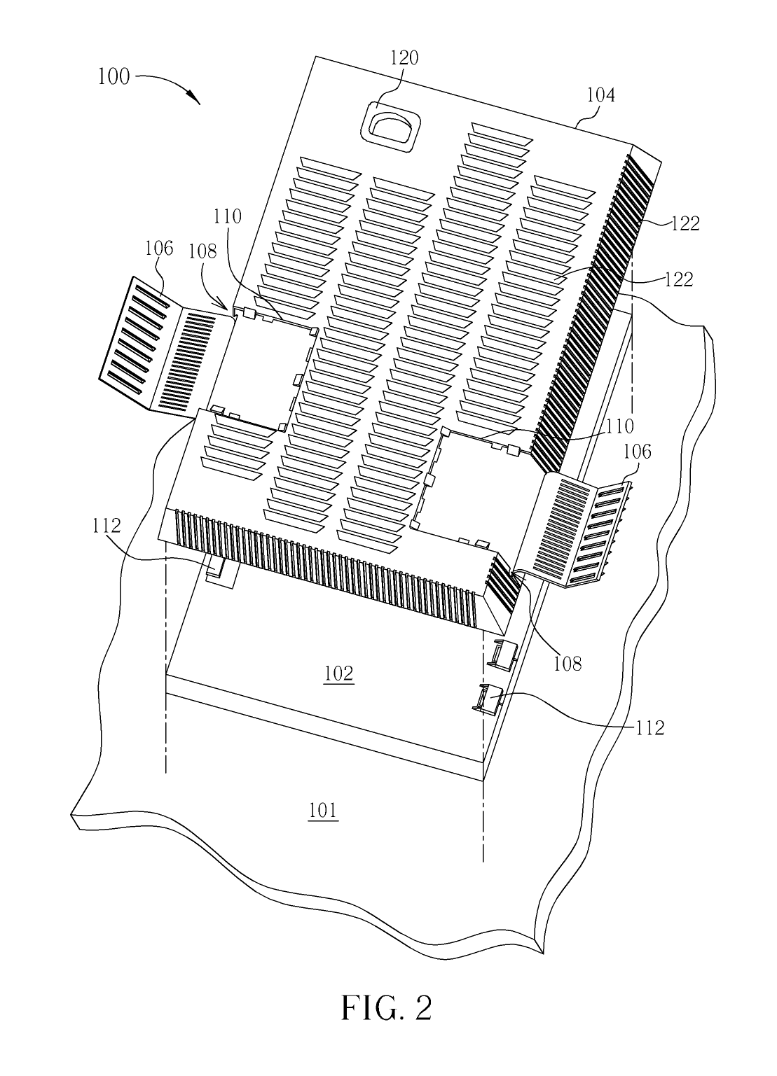

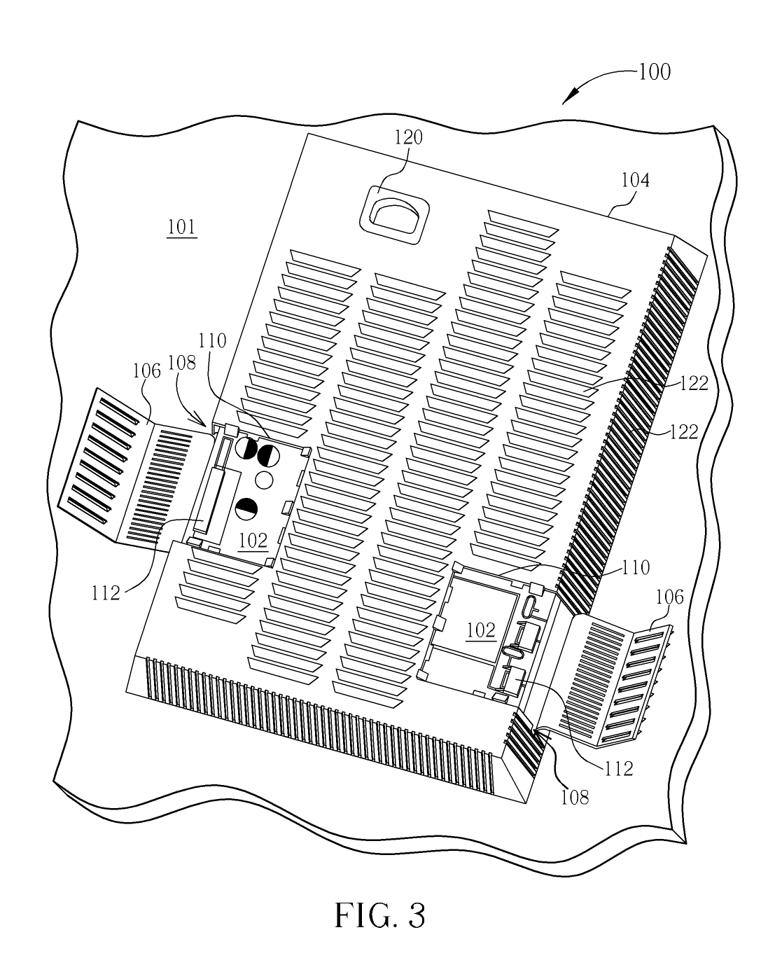

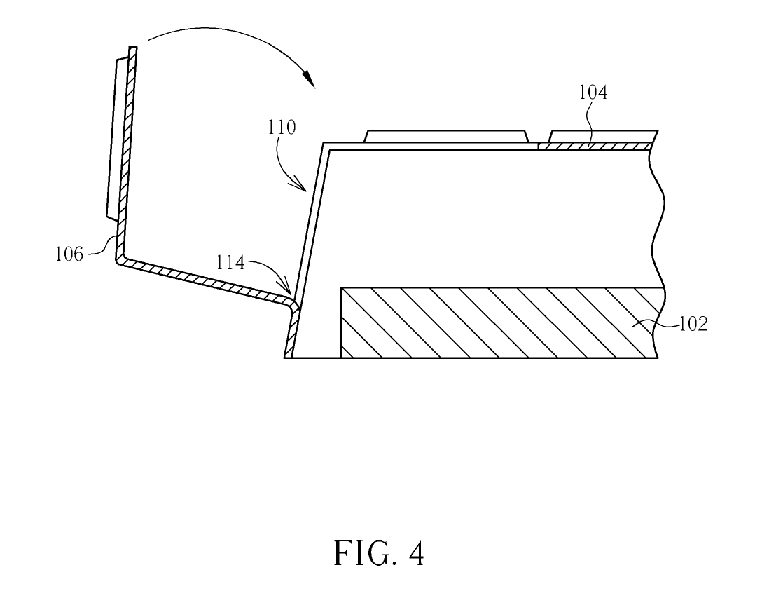

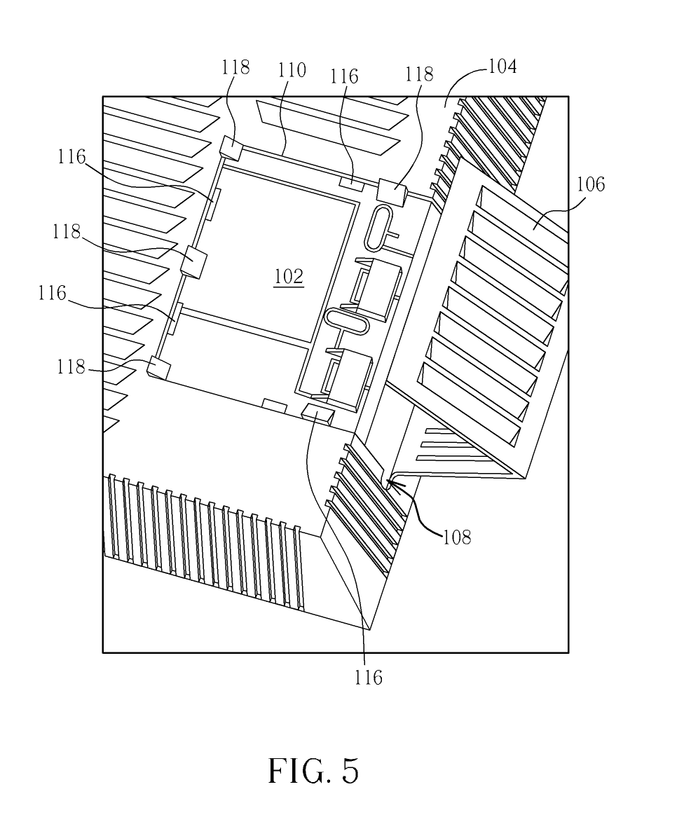

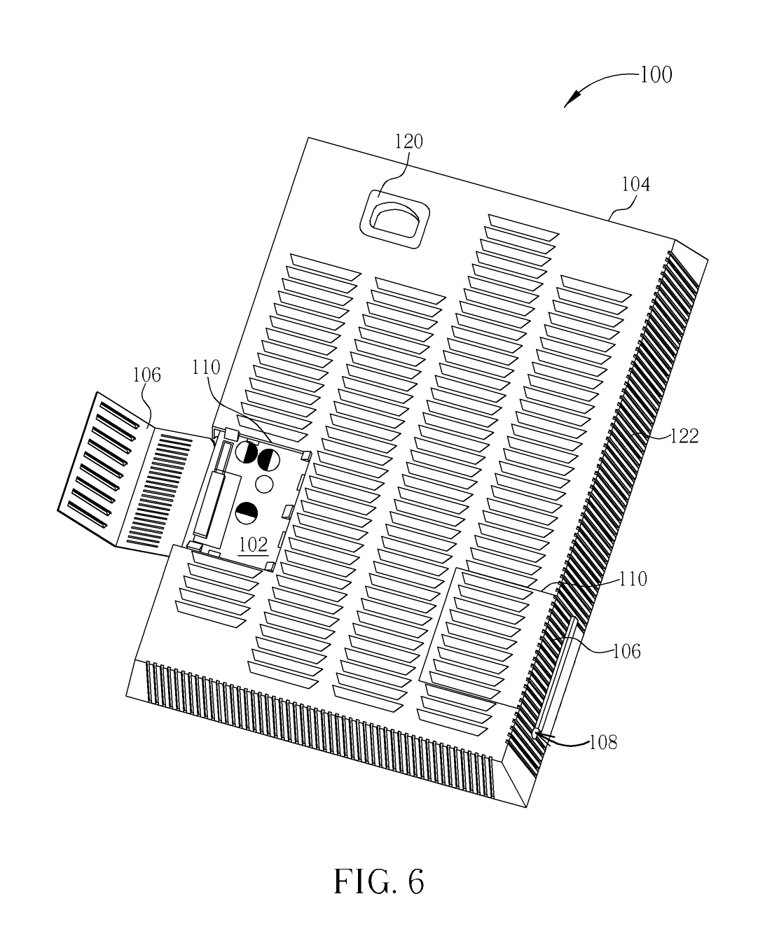

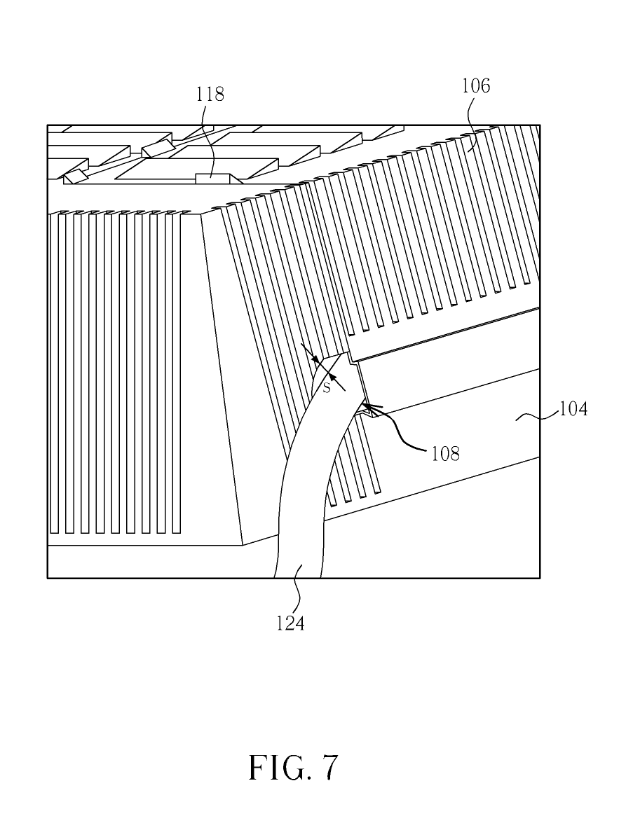

With reference to FIGS. 2 to 7, a shielding device is demonstrated according to a first preferred embodiment of the present invention, wherein FIG. 2 is an exploded diagram showing the shielding device covering the electronic device according to the present invention. FIG. 3 shows an open state of the lid of the shielding device while FIG. 4 shows a rotative state of the lid of the shielding device. FIG. 5 displays a corresponding state between the lid of the shielding device and the opening of the shielding device, and a closed state of the lid of the shielding device is shown in FIG. 6. As to FIG. 7, a shielding device with a complete wire assembly is illustrated. It is to be noted that the same components or parts in the embodiments of the present invention are designated by the same reference numerals. Further, the drawings described herein are for illustration purposes only, but are not intended to limit the scope of the present invention.

As shown in FIGS. 2 and 3, the present invention provides at least one electronic device 102 possibly inducing fire or electric shock, such as printed circuit boards and main boards with electronic or circuit components therein. In general, the electronic device 102 may be installed and connected to a substrate 101. In the example of a liquid crystal display structure, the substrate 101 could be a liquid crystal display module. The shielding device 100 may be installed on the electronic device 102, which is opposite to the substrate 101, to shield a great area of the electronic device 102. Consequently, the electronic device 102 can be substantially isolated from an outside environment by the shielding device 100 to lower the hazards of the electronic device 102. A detailed description is offered to the structure of the shielding device 100.

The shielding device 100 is disposed on the electronic device 102 and surrounds the electronic device 102 in order to shield the electronic device 102 without the need of covering the whole substrate 101. The shielding device 100 mainly includes a housing 104, a lid 106, and a connection hole 108, wherein the housing 104 has at least one opening 110 that corresponds to a connector 112 of the electronic device 102. In the present embodiment, the shielding device 100 may contain two openings 110 and two lids 106 corresponding to each other; the connector 112 may contain printed circuit boards wire terminals and so forth. In addition, the connection hole 108 is disposed on at least one of the perimeter of the opening 110 and the perimeter of the lid 106 of the housing 104 for a wire assembly purpose. Once the connection hole 108 touches either the perimeter of opening 110 or that of the lid 106, the connection hole 108 will form a non-closed opening as shown in FIGS. 2 and 3.

Furthermore, the shielding device 100 may selectively contain power connection holes 120, heat dissipating vents 122, and more. The shape and size of the power connection holes 120 are designed according to the shape and size of the corresponding power connector. Hence, the exposed portion of the electronic device 102 can be shielded effectively when the power connector is connected to the electronic device 102. The heat dissipating vents 122 may be distributed on the housing 104 and the lid 106 evenly or in a specific pattern to enhance heat-dissipating effect of the electronic device 102. It is to be noted that the quantity, location, size, and shape of the power connection holes 120 and the heat dissipating vents 122 are able to be altered upon product demands, but not limited to the present embodiment. The size and shape of the shielding device 100 is substantially corresponding to those of the electronic device 102. For instance, the dimension of the shielding device 100 is usually greater than that of the electronic device 102 so that it can surround all the edges and the upper surface of the electronic device 102; the shielding device 100 may be approximately a hexahedral case without a bottom. Again, the designs are not limited to the present embodiment.

As shown in FIG. 4, the perimeter of the lid 106 is connected to that of the opening 110. The lid 106 is able to rotate around the axis formed by the joint between the lid 106 and the opening 110 and cover the opening 110 to shield the connector 112 of the electronic device 102 as indicated in FIG. 3. Otherwise, the lid 106 will be in an open state so that the inside of the shielding device 100 and the electronic device 102 therein are exposed.

In the present invention, the shielding device 100 can be made of any material that is insulating as well as fireproof in order to achieve high voltage-resistant and fire-resistant effects. In a preferred embodiment of the present invention, both the housing 104 and the lid 106 can be made of materials that are flexible, insulating, and fireproof. The housing 104 and the lid 106 may be formed as a monolithic structure, but not limited to it. If the materials of the housing 104 and/or the lid 106 are flexible, insulating, and fireproof, the shielding device 100 is able to inhere with not only high voltage-resistant but also fire-resistant properties. Further, a better sealing and shielding effect of the housing 104 and the lid 106 is able to be achieved due to the bending ability of the lid 106, which results in a better coverage of the electronic device 102. Moreover, the joint between the housing 104 and the lid 106 will have rotation and twisting functions while the shielding device 100 is a flexible monolithic structure. In the case, it becomes either unnecessary to install the lid 106 onto the housing 104 or needless to offer a connecting component. Therefore, required quantity of display parts will be decreased, which leads to simplification in the fabrication process and reduction in cost.

In another embodiment of the present invention, the housing 104 and the lid 106 may also be made of rigid materials and/or metallic materials, such as a plastic material coated with a metallic layer, a metallic case coated with an insulating layer, or a plastic material containing metallic particles. Different materials will contribute different degrees of hardness or electromagnetic shielding effect to the shielding device. Alternatively, the housing 104 and the lid 106 can be two separate parts and further connected to each other by an adhesive, a connecting element, a pivot shaft, or by means of interlocking and embedding, which allows each part to be replaced individually.

Referring to FIG. 5, the housing 104 may further contain at least one positioning element 116 and at least one fastening element 118. There are four positioning elements 116 and four fastening elements 118 installed on the perimeter of the opening 110 as shown in the figure, which allows the closed lid 106 to be fixed between the upper positioning elements 116 and the lower fastening elements 118. In the present embodiment, the housing 104, the lid 106, the positioning elements 116, and the fastening elements 118 may be formed as a monolithic structure, but not limited to it.

In FIG. 6, the lid 106 in a closed state can fully shield the opening 110, and only expose the electronic device 102 via the connection hole 108. In FIG. 7, when the shielding device 100 is disposed on the electronic device 102, a connecting wire 124 will be connected to the electronic device 102 via the opening 110 and the connection hole 108. Later, the lid 106 is able to rotate freely and cover the opening 110 to shield the connector 112 of the electronic device 102 as shown in FIG. 3, forming an electronic module having a shielding device 100. In consequence, the connecting wire 124 extends outwardly through the connector 112 via the connection hole 108.

The terminal of the connecting wire 124, whose diameter is greater than the connecting wire 124 itself, is allowed to penetrate through the movable lid 106 and the opening 110. As a result, the connecting wire 124 can pass through the shielding device 100 simply via the connection hole 108 when the lid 106 of the shielding device 100 is in a closed state. In view of that, the size and shape of the connection hole 108 can be equal to, slightly larger than, or slightly smaller than (when the housing 104 and the lid 106 are flexible) those of the diameter of the connecting wire 124. According to the requirements of safety standards, a maximal gap S between an outer surface of the connecting wire 124 and one edge of the connection hole 108 is substantially less than or equal to 1 millimeter, but not limited to it.

Accordingly, the lid 106 provided by the present invention can be open and closed repeatedly without the need of applying additional adhesive or welding materials to attach the circumference of the lid 106 to that of the opening 110. While the connecting wire 124 or the electronic device 102 is being installed. replaced, adjusted, or repaired, the terminals of the connecting wire 124 and the electronic device 102 can be exposed simply by lifting up the lid 106, which allows the connecting wire 124 and the electronic device 102 to be connected to each other or separated from each other. Hence, the shielding device 100 of the present invention is able to enhance the convenience of wire assembly and rework of displays effectively.

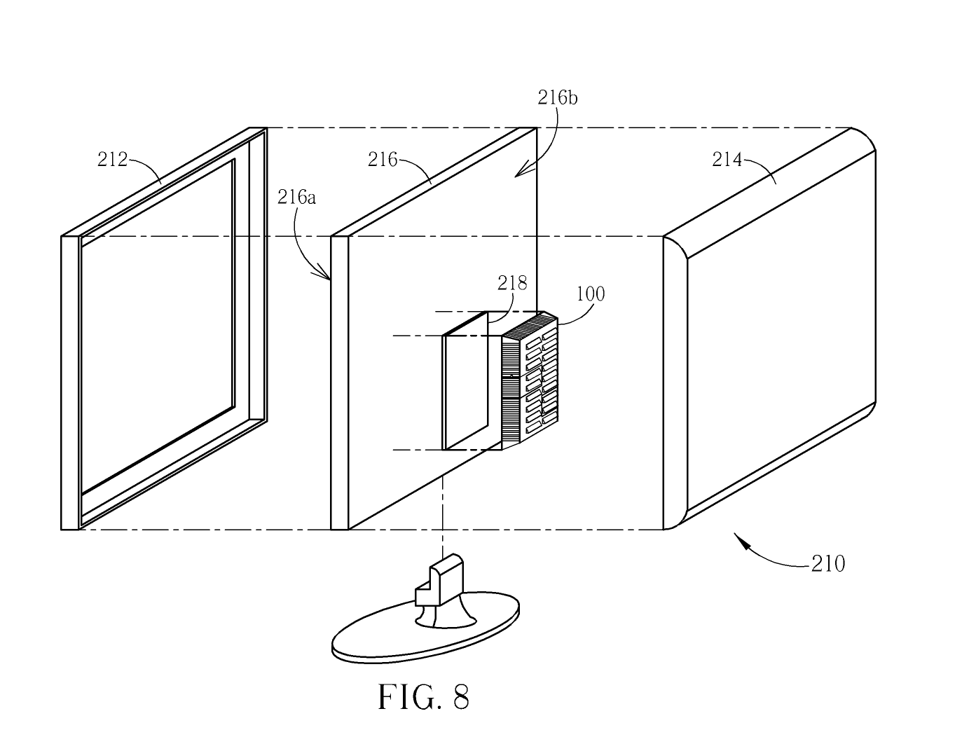

For complying with the requirements of safety standards, the shielding device of the present invention may preferably be applied to displays in order to shield the printed circuit boards and to increase its safety level. FIG. 8 shows a preferred embodiment of a display with a shielding device. As illustrated in FIG. 8, the display 210 includes a display module 216, printed circuit boards 218, a shielding device 100, a front frame 212, and a back shell 214.

Further, the display module 216 has a display screen 216a and a back surface 216b opposing the display screen 216a, wherein the display module 216 may be a liquid crystal display module, a plasma display module, etc., such as those with liquid crystal panels, driving chips, backlight modules, and optical films. The circuit board 218 is disposed on the back surface 216b of the display module 216. The front frame 212 is disposed at a side of the display module 216 opposing the circuit board 218 and exposing the display screen 216a of the display module 216. The back shell 214 covers the back surface 216b of the display module 216 and the shielding device 100. The front frame 212 and the back shell 214 may correspond to and combine with each other by means of screw locking, fastening, adhesion, and so on. Accordingly, the display module 216, the shielding device 100, and the printed circuit boards 218 will be covered by the front frame 212 and the back shell 214 respectively. Additionally, the shielding device 100 is installed on the printed circuit boards 218 and surrounding the printed circuit boards 218 while not covering the peripheral of the display module 216. That is, the shielding device 100 is installed between the printed circuit boards 218 and the back shell 214. And the shielding device 100 allows the printed circuit boards 218, which are flammable and have a leakage tendency, to be isolated from the outside. The fireproofing and insulating abilities of the display 210 will therefore be enhanced to meet the requirements of safety standards. Thus, it becomes unnecessary for the front frame 212 and the back shell 214 to be made of nonflammable and insulating materials, which leads to a vast reduction in cost of fabricating the display 210.

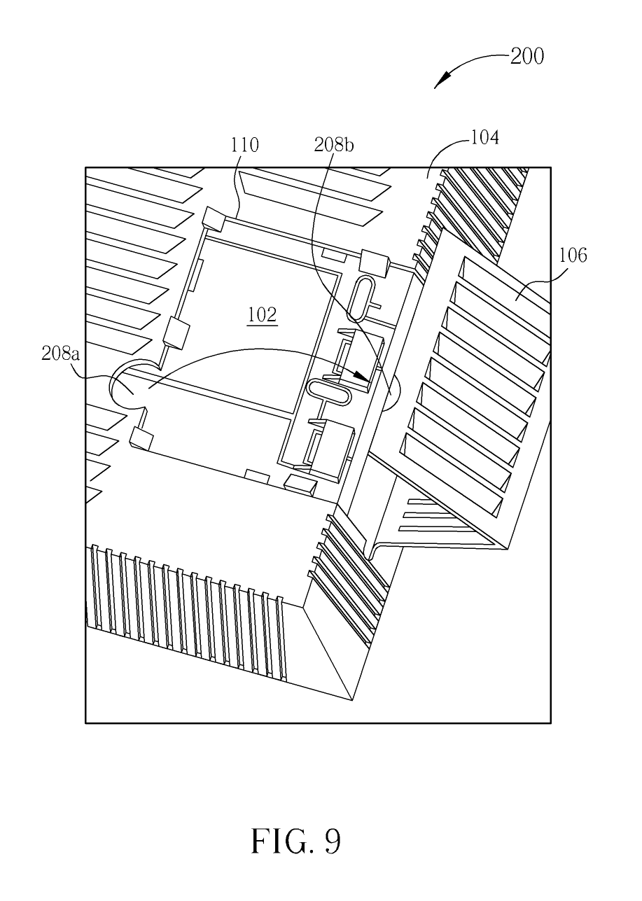

In the aforesaid embodiment, the connection hole 108 of the shielding device 100 is substantially formed on the perimeter of the opening 110 of the housing 104 and located at a side of the shielding device 100, which is near an axis 114. However, the present invention shall not be limited to this aspect; there may be different forms of the housing in other embodiments. For instance, the connection hole may have three possible installation sites, on the housing, on the lid, or on both of them. FIGS. 9 to 11 illustrate the second, third and fourth preferred embodiments of the present invention. The same components or parts in the embodiments of the present invention are designated by the same reference numerals and only their differences as compared to the first embodiment will be described while others will be omitted hereafter.

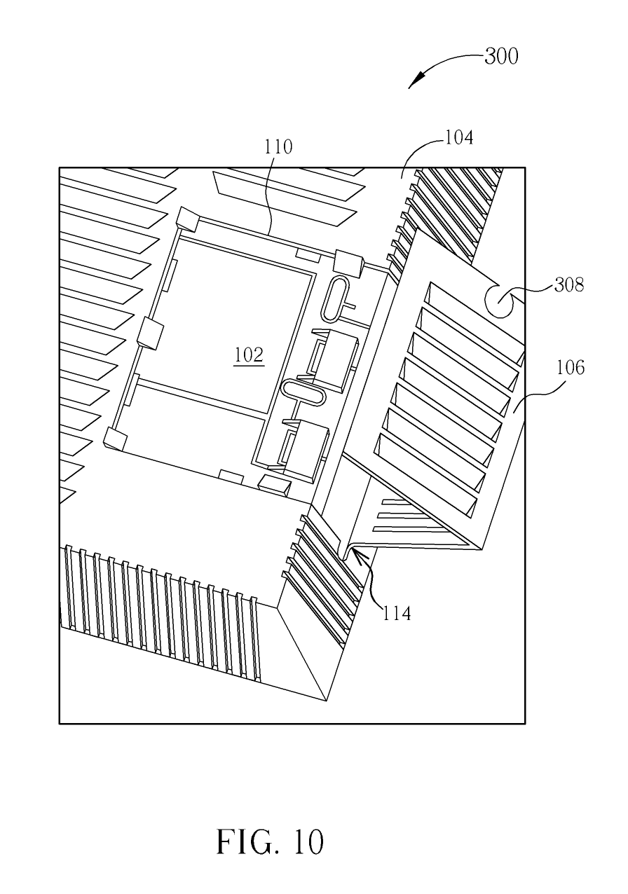

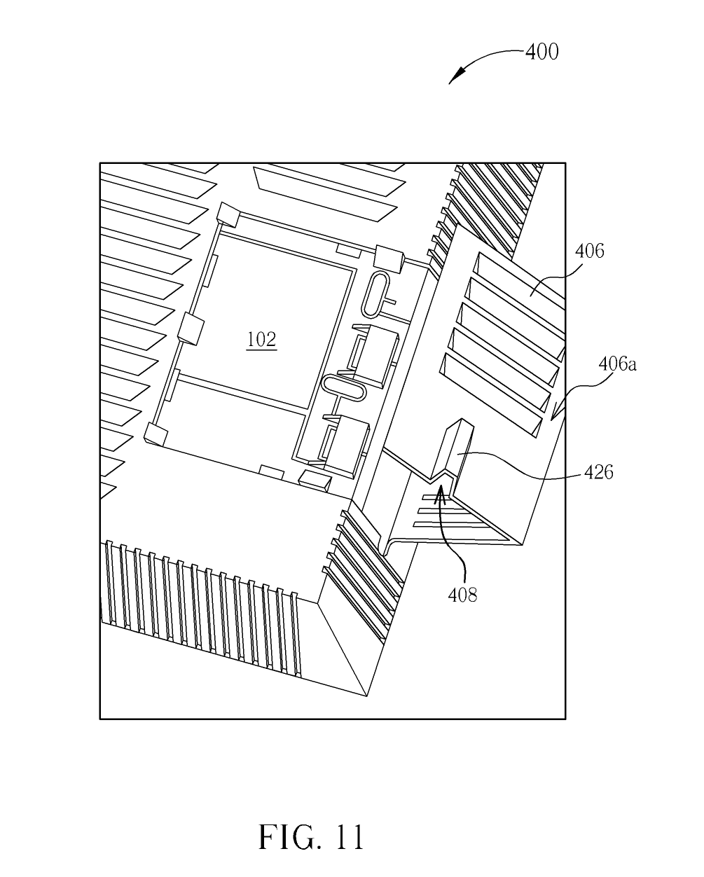

As shown in FIG. 9, connection holes 208a and 208b in the second embodiment are formed on the perimeter of the opening 110 of the housing 104 and the perimeter of the lid 106 respectively, and located on the surface of the shielding device 200. (i.e. on the same surface of the power connection holes 120). As to opening 110, the connection holes 208a and 208b are opposing the axis 114. When the lid 106 covers the opening 110, the connection hole 208a will be adjacent to and connected to the connection hole 208b, and the connecting wire 124 as shown in FIG. 7 will pass through the connection hole 208 and the connection hole 208b. FIG. 10 shows the third embodiment, in which a connection hole 308 is formed on the perimeter of the lid 106 of the shielding device 300, and the edge of the connection hole 308 is vertical to that of the axis 114. In FIG. 11, an outer surface 406a of a lid 406 has a bump structure 426 (or a concave structure for the inner surface of the lid 406). The bump structure 426 will define a peripheral of a connection hole 408 so that the connection hole 408 can be formed on the perimeter of the lid 406 of the shielding device 400. It is to be noted that the above-mentioned embodiments may be adjusted or combined with one another accordingly. For example, connection holes can be formed on the perimeter of the housing and the perimeter of the opening simultaneously; a plurality of connection holes can be formed on a perimeter of a single opening or a single perimeter of the housing.

To sum up, the connection holes of the present invention are formed on at least one of the perimeter of the opening of the housing and the perimeter of lid. When the lid covers the opening of the housing, the connecting wire of the electronic device can extend outwardly simply via the connection hole so that the exposed area of the electronic device can be reduced effectively. Further, a better sealing and shielding effects between the housing and the lid can be achieved since the shielding device in the present invention is made of nonflammable, insulating, and flexible materials. As a result, high voltage will be prevented and fireproof effects will be improved. Additionally, the joint between the housing and the lid have rotation and twisting functions if the shielding device is a flexible monolithic structure, so it becomes either unnecessary to install the lid onto the housing or needless to offer a connecting component, which leads to simplification in the fabrication process and reduction in cost. The convenience of connecting wire assembly and module rework will also be enhanced. Hence, there is no longer a need to use non-flame resistant materials for the consuming liquid crystal TV cases or other consuming components so as to reduce material cost at a great amount.

Those skilled in the art will readily observe that numerous modifications and alterations of the device and method may be made while retaining the teachings of the invention.

What is claimed is:

1. A shielding device disposed on an electronic device and surrounding the electronic device, the shielding device comprising:
a housing having at least one opening corresponding to a connector of the electronic device;
a lid covering the opening to shield the connector, a perimeter of the lid connected to a perimeter of the opening; and
a connection hole disposed on at least one of the perimeter of the opening and the perimeter of the lid.

2. The shielding device of claim 1, wherein the housing and the lid comprise a material being flexible, insulating, and fireproof.

3. The shielding device of claim 1, wherein the electronic device is connected to at least one connecting wire and the connecting wire extends outwardly through the shielding device via the connection hole.

4. The shielding device of claim 3, wherein a maximal gap between an outer surface of the connecting wire and one edge of the connection hole is substantially less than or equal to 1 millimeter.

5. The shielding device of claim 1, wherein the housing further comprises at least one positioning element disposed on the perimeter of the opening.

6. The shielding device of claim 5, wherein the housing further comprises at least one fastening element disposed on the perimeter of the opening, and lid fastening elements fixed between the positioning element and the fastening element when the lid is closed.

7. The shielding device of claim 6, wherein the housing, the lid, the positioning element, and the fastening element are a monolithic structure.

8. The shielding device of claim 1, wherein the housing and the lid are a monolithic structure.

9. The shielding device of claim 1, wherein the connection hole comprises a non-closed opening.

10. A display, comprising:
a display module having a display screen and a back surface opposing the display screen;
a circuit board disposed on the back surface of the display module;
a shielding device disposed on the circuit board and surrounding the circuit board, comprising:
a housing having at least one opening corresponding to a connector of the circuit board;
a lid covering the opening to shield the connector, a perimeter of the lid being connected to a perimeter of the opening; and
a connection hole disposed on at least one of the perimeter of the opening and the perimeter of the lid;
a front frame disposed at a side of the display module opposing the circuit board and exposing the display screen of the display module; and
a back shell covering the back surface of the display module and the shielding device.

11. The display of claim 10, wherein the housing and the lid comprise a flexible, insulating, and fireproof material.

12. The display of claim 10, wherein the circuit board is connected to at least one connecting wire and the connecting wire extends outwardly through the shielding device via the connection hole.

13. The display of claim 12, wherein a maximal gap between an outer surface of the connecting wire and one edge of the connection hole is less than or equal to 1 millimeter substantially.

14. The display of claim 10, wherein the front frame and the back shell are made of non-flame resistant and non-insulating materials.
